(19) United States
(12) Patent Application Publication
(10) Pub. No.: US 2011/0058438 A1
(43) Pub. Date: Mar. 10, 2011

(54) SEMICONDUCTOR MEMORY DEVICE AND REFRESH CONTROL METHOD OF MEMORY SYSTEM

(75) Inventor: Akihiko KAGAMI, Tokyo (JP)

(73) Assignee: ELPIDA MEMORY, INC., Tokyo (JP)

(21) Appl. No.: 12/946,507

(22) Filed: Nov. 15, 2010

Related U.S. Application Data
(62) Division of application No. 11/996,694, filed on Jan. 24, 2008.

(30) Foreign Application Priority Data
Jul. 26, 2005 (JP) 2005-216429

(51) Int. Cl. G11C 7/00

(52) U.S. Cl. 365/222

(57) ABSTRACT

There are provided a semiconductor memory device and others having a preferable operation efficiency and eliminating complicated control when refreshing a memory array divided into a plurality of banks. The semiconductor memory device includes a memory array (10) divided into a plurality of banks (0 to 3) each of which can be controlled independently and its peripheral circuit. Each of the banks 0 to 3 has a refresh counter (24) for generating a row address to be refreshed. A control circuit (20) executes refresh operation for the bank selected according to the bank selection data in accordance with a refresh request having bank selection data for selecting a plurality of banks 0 to 3 in an arbitrary combination. On the other hand, the control circuit (3) performs control no to execute refresh operation for the bank not selected according to the bank selection data.

By performing such a refresh control, it is possible to rapidly perform each refresh operation by eliminating refresh of a bank in a busy state, there by improving the operation efficiency.

### CROSS REFERENCE TO RELATED APPLICATIONS

This application is a divisional of U.S. patent application Ser. No. 11/996,694, filed on Jan. 24, 2008, which is a national stage of International Application No. PCT/JP2006/314304, filed on Jul. 19, 2006, which claims priority from Japanese Patent Application No. 2005-216429, filed on Jul. 26, 2005, the contents of all of which are incorporated herein by reference in their entirety.

### TECHNICAL FIELD

The present invention relates to a semiconductor memory device in which a memory cell array is divided into a plurality of banks and read/write operation for each bank can be controlled individually. Particularly, the present invention relates to a semiconductor memory device such as a DRAM (Dynamic Random Access Memory) which is configured to be capable of an auto refresh operation for each bank at predetermined refresh intervals in a normal operation, and relates to a memory system including such a semiconductor memory device.

### BACKGROUND ART

A configuration of a general DRAM is known in which a memory array is divided into a plurality of banks so that read/write operation of the DRAM can be independently controlled for the respective banks. When the DRAM is composed of, for example, four banks, only one desired bank is activated and the read/write operation can be performed by issuing various types of commands to which a 2-bit bank address is added.

Meanwhile, it is necessary to perform a refresh operation with a predetermined refresh period to hold data stored as electric charge in memory cells of the DRAM. Generally, in a normal operation, an auto-refresh function is employed which performs a refresh operation for a row address counted up by a refresh counter at predetermined intervals. Basically, control in the refresh operation can be performed commonly for all the banks, and thus the refresh operation is simultaneously performed for all the banks. For example, when it is supposed that the refresh period is 64 ms and the number of word lines is 8192, the auto-refresh is repeatedly performed for all the banks every time a refresh interval of 7.8 μs passes.

Further, when the refresh operation is simultaneously performed for all the banks, there is a possibility of an increase in peak current and a reduction in use efficiency of a bus during the refresh operation. Thus, a DRAM is proposed in which a refresh operation is performed only for some of a plurality of banks, (refer to, for example, Patent Documents 1 and 2).

### Patent Document 1: Japanese Unexamined Patent Application Publication No. 2001-35152

Patent Document 2: Japanese Unexamined Patent Application Publication No. H05-151772

### DISCLOSURE OF INVENTION

### Problems to be Solved by the Invention

The auto-refresh operation for the DRAM must be performed at a timing of the refresh interval regardless of whether or not read/write operation for a bank to be refreshed is being performed. The refresh operation can be started at once when the bank to be refreshed is in an idle state, however complex control is required to be performed in the refresh operation when the bank to be refreshed is in a busy state due to the read/write operation. Here, the busy state means that the bank is in an active state, and the idle state means that the bank is in a non-active state. That is, the control is performed according to a process in which the operation of the bank to be refreshed is interrupted to perform a precharge operation for the bank rapidly, the refresh operation is performed after the bank is shifted to the idle state, and then the bank is shifted to the active state to resume the interrupted operation after the completion of the refresh operation. Since a series of the process requires a considerable number of clocks, a processing time is accumulated and load on the control is increased when it is taken into consideration that the refresh interval is short. Moreover, such a control is required in a case where even one bank is in the busy state when the refresh operation is simultaneously performed for all the banks. Accordingly, the above process is performed considerably frequently as a whole, and a problem arises in that the operation efficiency of the DRAM is deteriorated.

As to this point, even when the refresh operation is performed only for some of a plurality of banks as described in Patent Documents 1 and 2, a similar problem also arises in that the above process is required for the bank in the busy state.

An object of the present invention is to provide a semiconductor memory device which makes a complex control performed for a bank in a busy state unnecessary when a refresh operation is performed for a memory array divided into a plurality of banks, reliably completes the refresh operation in a short time, and has excellent operation efficiency.

### Means for Solving the Problems

An aspect of the present invention is a semiconductor memory device comprising: a memory array divided into a plurality of banks each capable of being individually controlled; a refresh address generating circuit, provided in each of the plurality of banks, for generating a row address to be refreshed; and a refresh control means for controlling to perform a refresh operation for a bank selected based on bank select data and not to perform a refresh operation for a bank not selected based on the bank select data, in response to a refresh request to which the bank select data representing selected banks of an arbitrary combination of the plurality of banks is attached.

According to the semiconductor memory device of the present invention, when performing the refresh operation for the memory array, the refresh request can be issued by freely selecting only banks to be refreshed in accordance with the operation state. Regarding each bank selected to be refreshed, the refresh operation for a row address generated by the refresh address generating circuit is performed, and regarding each bank not selected to be refreshed, the refresh operation is not performed. Thus, the control required for refreshing an operating bank when issuing the refresh request (That is, a series of process of suspending the operation of the bank and resuming it after the refresh operation, or the like) does not need to be performed, and every refresh operation can be rapidly completed so as to improve the operating efficiency of the semiconductor memory device.

In the semiconductor memory device of the present invention, the bank select data may be N-bit data corresponding to 2^{N} kinds of combinations each including a selection of respective N banks

In this case, the bank select data of N bits can be assigned to predetermined N bits included in an address externally input at the time of the refresh request.

In the semiconductor memory device of the present invention, the refresh operation may be an auto refresh operation sequentially performed at predetermined refresh intervals in a normal operation, and the refresh address generating circuit corresponding to a bank selected based on the bank select data may be configured to update the row address to be refreshed at each of the refresh intervals.

In the semiconductor memory device of the present invention, a bank select auto refresh command for instructing the auto refresh operation for a bank selected by the bank select data and a normal auto refresh command for instructing the auto refresh operation for all banks may be respectively defined as two kinds of commands requiring the auto refresh operation, and the refresh control means may determine the bank select auto refresh command and the normal auto refresh command so as to perform the auto refresh operation which is requested.

In this case, a common auto refresh command to the bank select auto refresh command and the normal auto refresh may be defined, and the refresh control means may store set data for selectively setting a bank select auto refresh and a normal auto refresh in a mode register and may determine the auto refresh command and the normal refresh command based on the set data stored in the mode register when the common auto refresh command is issued.

An aspect of the present invention is a refresh control method of a memory system including a semiconductor memory device which is provided with a memory array divided into a plurality of banks each capable of being individually controlled and performs a refresh operation for a bank selected from the plurality of banks, the method comprising the steps of: determining whether or not each of the plurality of banks is in a busy state at a predetermined timing for the refresh operation, establishing bank select data representing only one or more banks not in the busy state, and issuing a refresh request with the established bank select data; and performing the refresh operation for a bank selected based on the bank select data in the semiconductor memory device to which the refresh request received, while not performing the refresh operation for a bank not selected based on the bank select data.

In the refresh control method of the present invention, the bank select data may be N-bit data corresponding to 2^{N} kinds of combinations each including a selection of respective N banks in the semiconductor memory device.

In the refresh control method of the present invention, the refresh operation may be an auto refresh operation sequentially performed at predetermined refresh intervals in a normal operation, and a bank select auto refresh command for instructing the auto refresh operation for a bank selected by the bank select data may be defined.

In the refresh control method of the present invention, at each of the refresh intervals, the bank select data may be established by selecting one or more banks which are not in the busy state, and the bank select auto refresh command with the established bank select data may be issued.

In this case, in each of time periods each including a predetermined number of the refresh intervals, when the number of refresh operations performed for each bank in response to the bank select auto refresh command is less than the predetermined number, auto refresh operations may be performed a number of times by which at least the lacking number of refresh operations is replenished for each bank.

### Effect of the Invention

According to the present invention, a refresh operation of a semiconductor memory device having a memory cell array divided into a plurality of banks can be performed only for banks of an arbitrary combination pattern selected from the plurality of banks. Therefore, when a certain bank is in a busy state for read/write operation, this bank can be excluded from refresh targets. Accordingly, a series of process from suspending the operation of the bank in the refresh operation to resuming it does not need to be performed, and every refresh operation can be rapidly completed, so that the operating efficiency of the semiconductor memory device can be improved.

### BRIEF DESCRIPTION OF DRAWINGS

FIG. 1 is a block diagram showing an entire configuration of a DRAM of an embodiment.

FIG. 2 is a diagram showing types of main commands used in the DRAM of the embodiment.

FIG. 3 is a diagram showing a configuration example of a mode register and an extended mode register set by an MRS command and an EMRS command.

FIG. 4 is a specific example of a control flow when a direct auto-refresh operation is performed in the DRAM of the embodiment.

FIG. 5 is a specific example of operation waveforms when the direct auto-refresh is performed.

FIG. 6 is a diagram showing a combination of bank selection based on bank select data of a DRF command.

FIG. 7 is a diagram showing operation waveforms as a comparative example with the embodiment when performing a conventional auto-refresh operation.

FIG. 8 is a diagram showing a specific example of a control method for replenishing the lacking number of refresh operations for each bank.

FIG. 9 is a diagram showing a specific example of a control method for replenishing the lacking number of refresh operations for each bank using a conventional REF command.

### DESCRIPTION OF SYMBOLS

10 memory array (banks 0 to 3)
11 row circuit
12 row address latch
13 column circuit
20 control circuit
21 address register
22 column address latch
23 I/O circuit
24 refresh counter
25 address selector
201 command decoder
202a mode register
202b extended mode register
203 bank controller

### BEST MODE FOR CARRYING OUT THE INVENTION

An embodiment of the present invention will be explained below with reference to drawings. In the embodiment, the present invention is applied to a memory system including a semiconductor memory device such as a DRAM (Dynamic Random Access Memory) and the like having a configuration capable of performing a long-period refresh operation for the purpose of reducing power consumption. Hereinafter, a configuration in which a DDR-SDRAM (Double Data Rate Synchronous DRAM) composed of four banks will be explained as an example of a synchronous type DRAM.

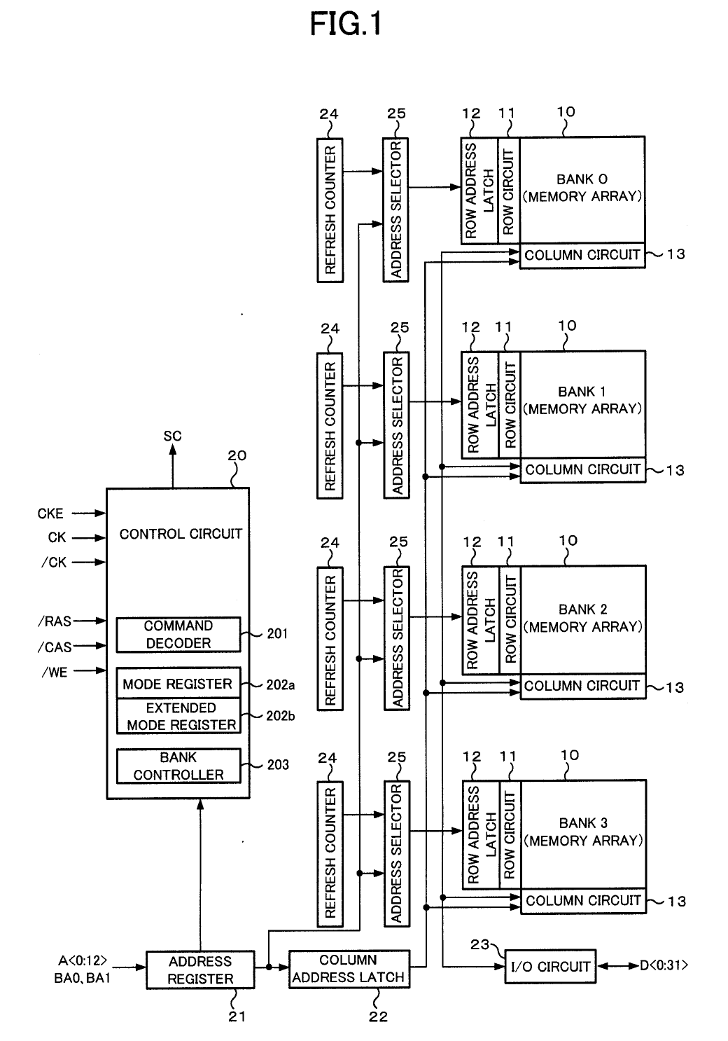

FIG. 1 is a block diagram showing an entire configuration of the DRAM of the embodiment. The DRAM shown in FIG. 1 includes a memory array 10 in which a plurality of word lines in a row direction and a plurality of bit lines in a column direction are arranged in a matrix form, and a plurality of memory cells are formed at intersections between the plurality of word lines and the plurality of bit lines. The memory array 10 is divided into four banks (shown as banks 0, 1, 2 and 3 in the drawing), each of which can be independently controlled. These banks have the same size and the same configuration. The DRAM shown in FIG. 1 includes row circuits 11, row address latches 12, column circuits 13, a control circuit 20, an address register 21, a column address latch 22, an I/O circuit 23, refresh counters 24, and address selectors 25, in addition to the memory array 10.

In the configuration of FIG. 1, the respective banks 0 to 3 of the memory array 10 are provided with four row circuits 11 including word drivers and row decoders connected to the word lines and four column circuits 13 including sense amplifiers and column decoders connected to the bit lines. Further, four row address latches 12 are provided corresponding to the respective banks 0 to 3 of the memory array 10 to latch a row address selected in the row circuit 11. Further, four refresh counters 24 and four address selectors 25 are provided for the respective banks 0 to 3. The refresh counter 24 functions as a refresh address generating circuit of the present invention and sequentially counts a row address of a word line to be refreshed. The address selector 25 selectively switches the output of the refresh counter 24 and the output of the later-described address register 21, and sends it to the row address latch 12.

Meanwhile, as common components of the DRAM, there are provided the control circuit 20 for controlling a read/write operation and a refresh operation for the memory array 10, the address register 21 for holding a 13-bit address A<0:12> and a 2-bit bank address (BA0, BA1) respectively input from the outside, the column address latch 22 for latching a column address among the address data stored in the address register 21, and the I/O circuit 23 for controlling the input/output of 32-bit data D<0:31> from/to the outside when the memory array 10 is accessed.

The control circuit 20 includes a command decoder 201 for determining a command input to the DRAM from an external controller, a mode register 202a and an extended mode register 202b for holding data for setting operation modes of the DRAM, and a bank controller 203 for individually controlling the operating states of the respective banks 0 to 3. The control circuit 20 outputs a control signal SC for controlling the operation of the DRAM and supplies it to the respective components through connection paths (not shown). Further, the address data stored in the address register 21 is sent to the control circuit 20 when necessary.

A clock CK and a clock /CK which have the same frequency and phases reverse to each other are input to the control circuit 20. The specification of the DDR-SDRAM makes it possible to perform a high speed operation by synchronizing edges of the clocks CK and /CK. Further, a control signal CKE for switching validity/invalidity of the clocks CK and /CK is input to the control circuit 20.

Further, a chip select signal (/CS), a row address strobe signal (/RAS), a column address strobe signal (/CAS) and a write enable signal (/WE) are input to the control circuit 20 respectively as control signals from the outside. Note that the symbol “/” means that a signal becomes active when it is in a low level. Since commands issued to the DRAM is specified by a combination pattern of the respective control signals described above, the command decoder 201 determines a type of each command based on the combination pattern.

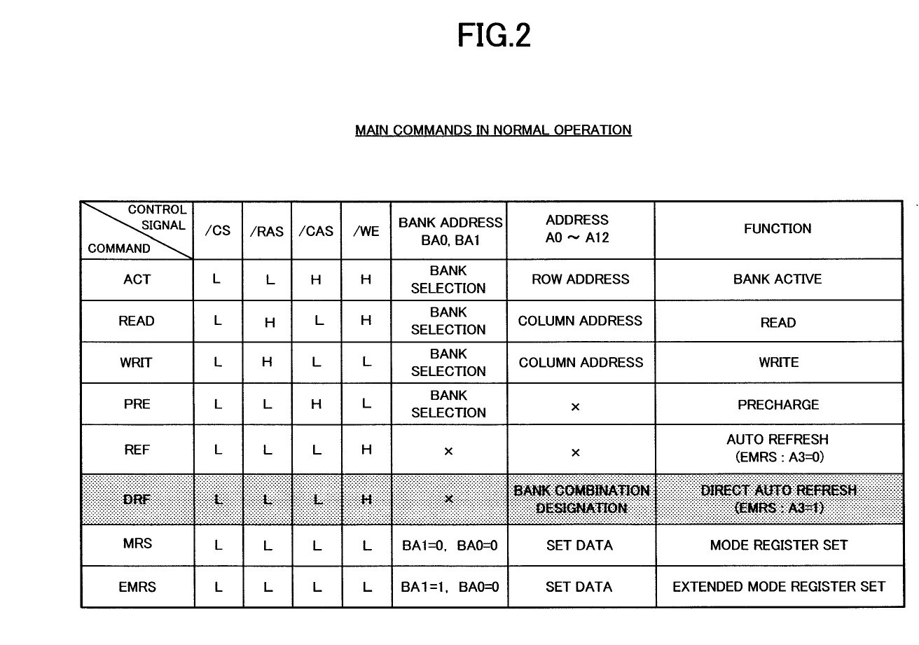

FIG. 2 is a diagram showing the types of main commands used in the DRAM of the embodiment. The example of FIG. 2 shows eight types of commands including a DRF command which is unique in the embodiment, respectively as typical commands issued to the DRAM of the embodiment in a normal operation. The combination patterns of the control signals and the states of bank address (BA0, BA1) and an address A0 to A12 are shown in FIG. 2, in addition to functions of the respective commands.

Note that various commands for performing various types of functions of the DRAM are actually set, in addition to the types of the commands shown in FIG. 2. Further, commands relating to a self-refresh and a power down, which are performed in a data holding state or the like other than the normal operation, are also set. In FIG. 2, commands useful to understand the operation of the embodiment are only shown.

In FIG. 2, an ACT command instructs to place a designated row address in the active state in a selected bank. A READ command instructs to start a burst read operation from a row address in the active state and a designated column address in a selected bank. A WRIT command instructs to start a burst write operation from a row address in the active state and a designated column address in a selected bank. A PRE command instructs to perform a precharge operation for a selected bank. Note that the ACT command, the READ command and the WRIT command require selecting any of the four banks 0 to 3 using the 2-bit bank address (BA0, BA1).

Two types of commands: an REF command and a DRF command are prepared in relation to the auto-refresh function in the embodiment. The REF command corresponds to a normal auto-refresh command of the present invention and instructs to perform an auto-refresh operation for all the four banks 0 to 3. The DRF command corresponds to a bank selecting refresh command of the present invention and instructs to perform the auto-refresh operation for banks of an arbitrary combination pattern selected from the four banks 0 to 3 (hereinafter, referred to as a direct auto-refresh). The direct auto-refresh is a unique function in the embodiment, and the specific operation thereof will be described later. These REF command and DRF command are specified as a command having a common combination pattern of control signals, respectively, and are set such that they can be switched in accordance with the contents of the extended mode register as described later.

An MRS command instructs the mode register 202a of FIG. 1 to set desired set data. Further, an EMRS command instructs the extended mode register 202b of FIG. 1 to set desired set data. When the MRS command or the EMRS command is issued, they are distinguished by the bank address (BA0, BA1) and the set data is sent using the address A0 to A12.

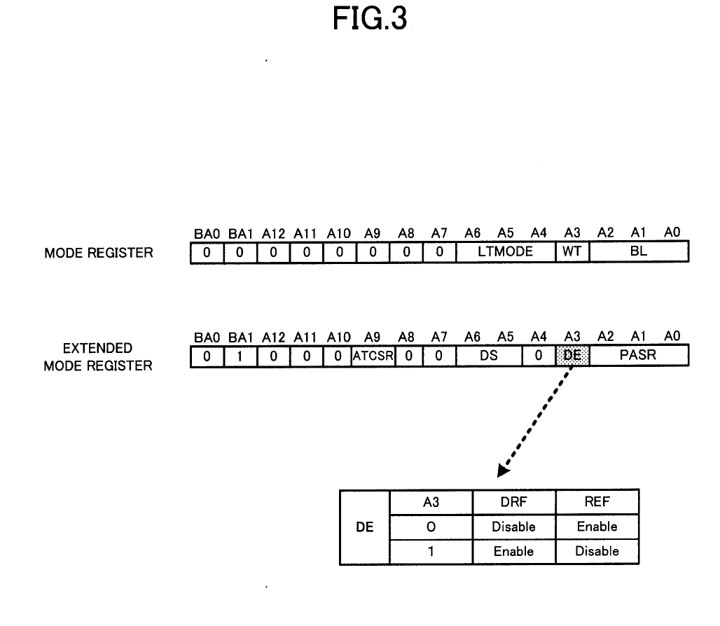

FIG. 3 shows a configuration example of the mode register 202a and the extended mode register 202b set by the MRS and EMRS commands. As shown in FIG. 3, set data, for example, /CAS latency (LTMODE), burst length (BL), burst sequence (WT) and the like is stored in the mode register 202a set by the MRS command. Further, DRF enable DE relating to the auto-refresh function of the embodiment is stored in the extended mode register 202b set by the EMRS command, in addition to, for example, automatic temperature compensation self-refresh (ATCSR) and partial array self-refresh (PASR). Explanation of the set data other than the DRF enable DE is omitted.

As shown in FIG. 3, the DRF enable DE is allocated to a bit position of an address bit A3 included in the EMRS command in the extended mode register 202b. Either of the auto-refresh and the direct auto-refresh can be set according to whether the data enable DRF is 0 or 1. That is, when 0 is set to the DRF enable DE (disable), the REF command is set. On the other hand, when 1 is set to the DRF enable DE (enable), the DRF command is set. In this manner, the auto-refresh and the direct auto-refresh can be selectively set by issuing the EMRS command.

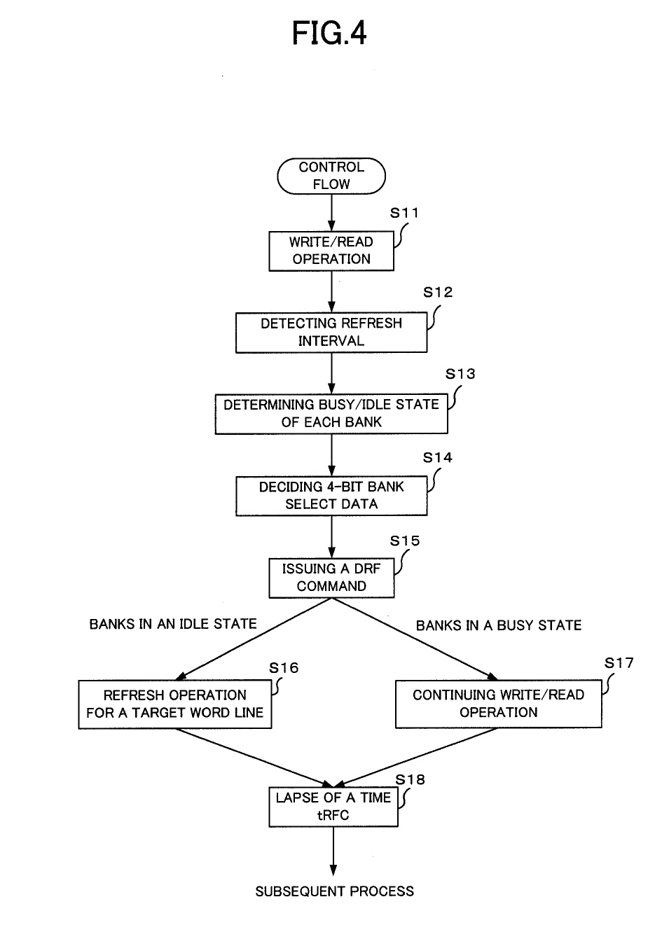

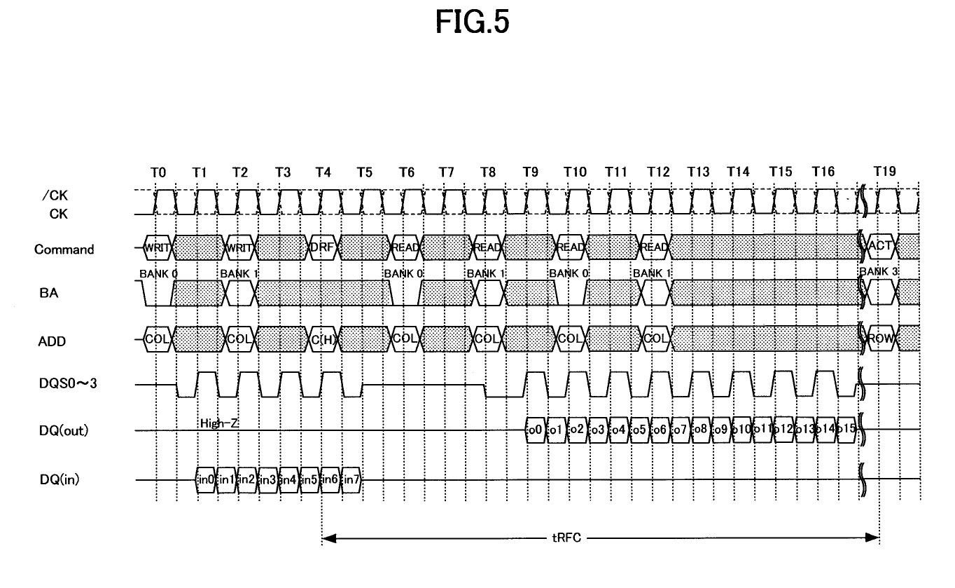

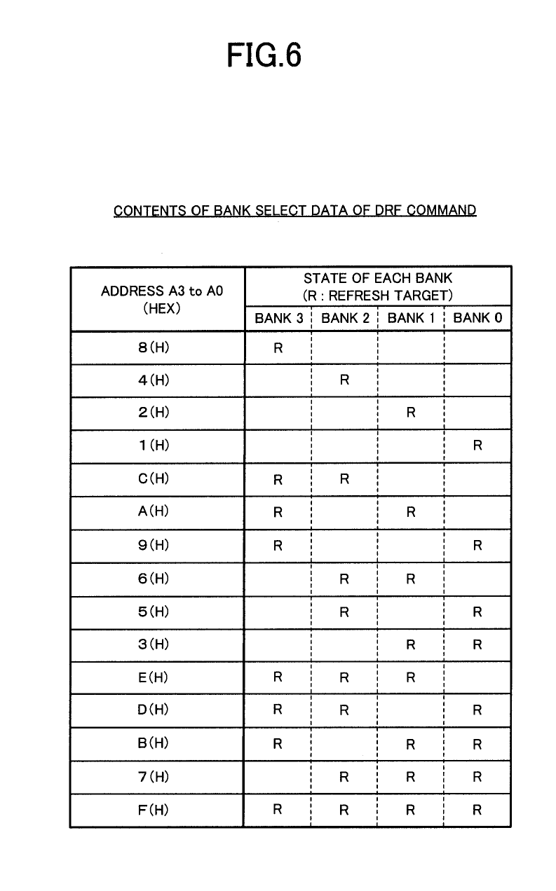

Next, a direct auto-refresh operation of the embodiment will be explained referring to FIGS. 4 to 6. FIG. 4 shows a specific example of a control flow when the direct auto-refresh operation is performed in the DRAM of the embodiment. FIG. 5 shows a specific example of operation waveforms when the direct auto-refresh operation is performed. FIG. 6 is a diagram showing a combination of bank selection based on the bank select data of the DRF command.

Note that FIG. 5 shows operation waveforms on a time axis within a predetermined range as to a command issued by an external controller, including a bank address (BA: overlapped two bits are indicated), an address (ADD: respective overlapped bits of the address are indicated), data strobes DQS0 to DQS3 for specifying data input/output timings, data output DQ(out) in a read operation, and data input DQ(in) in a write operation, respectively using the clocks CK and /CK for specifying operation timings each as a reference.

It is assumed that 1 is previously set to the DRF enable by the EMRS command and the direct auto-refresh is selectively set prior to the start of the control flow as shown in FIG. 4. Then, the write operation or the read operation is performed by selecting any of the banks 0 to 3 at a predetermined timing in the normal operation (step S11). In the example of the operation waveforms of FIG. 5, the WRIT command is issued to the bank 0 at a cycle T0, and the WRIT command is issued to the bank 1 at a cycle T2. With this operation, the write operation is performed, and each 4 bits of data inputs in0 to in7 of 8 bits in total is captured into the I/O circuit 23 and written to a corresponding address.

Next, in FIG. 4, it is detected that a previously set refresh interval is reached (step S12). Although the DRAM is generally required to perform a refresh operation for the memory cells with a predetermined refresh period, refresh operations for respective word lines corresponding to each row address sequentially counted by the refresh counter 24 are sequentially performed at dispersed timings within each refresh period. For example, in a case where the refresh period is 64 ms and the number of the word lines is 8192, the refresh operation is performed at refresh intervals of 64 ms/8192 lines=7.8 μs. At step S12, the timing at which the refresh interval has passed is detected using the timing of the last time refresh operation as a starting point.

Next, the external controller determines whether each of the banks 0 to 3 is in the busy state or in the idle state before issuing a refresh request (step S13). That is, since banks selected for the read/write operation are maintained in the busy state until a given time passes, these banks are not selected to be refreshed, while only other banks in the idle state are selected to be refreshed. The external controller can determine whether each of the banks 0 to 3 is in the busy state or in the idle state based on a state of an immediately issued command and its timing.

Then, 4-bit bank select data to be added to the DRF command is decided based on the determination result at step S13 (step S14). As shown in FIG. 6, the bank select data is assigned to lower 4 bits (A3 to A0) of the address, and combinations of the banks selected to be refreshed (indicated by R) are different from one another regarding all of 16 kinds of bit patterns using A3 to A0. The combinations include, for example, patterns for selecting one bank (four kinds), patterns for selecting two banks (six kinds), patterns for selecting three banks (four kinds), and a pattern for selecting all the four banks (one kind), respectively among the four banks 0 to 3. In this manner, even when the four banks 0 to 3 are in the busy state/the idle state in any combination, only the banks in the idle state can be reliably selected to be refreshed by the DRF command.

Subsequently, the DRF command, to which the bank select data of step S14 is added, is issued (step S15). The DRF command is issued in a state where control signals are combined as in FIG. 2 and desired bank select data is set to the lower 4 bits of the address. In the example of FIG. 5, the write operation for the banks 0 and 1 is immediately performed, and the banks 0 and 1 are in the busy state while the banks 2 and 3 are in the idle state, so that C(H) of FIG. 6 is set as the bank select data to refresh the banks 2 and 3. Then, at a cycle T4, the DRF command is issued in a state where C(H) is set to the lower 4 bits of the address.

When the DRF command is determined by the command decoder 201, the refresh operation for the word lines corresponding to count values of the respective refresh counters 24 are performed as to the banks in the idle state under the control of the bank controller 203 (step S16). On the other hand, the refresh operation for the banks in the busy state is not performed under the control of the bank controller 203, and thereby the read/write operation which has been performed can be continued without being interrupted (step S17).

In the example of FIG. 5, the READ command is issued to the bank 0 at cycles T6 and T10 and the READ command is issued to the bank 1 at cycles T8 and T12, respectively during the refresh operation for the banks 2 and 3. As a result, the read operation is performed, and data outputs o0 to o15 of 16 bits in total are output to the outside through the I/O circuit 23.

Next, it is determined whether or not a time tRFC required from the issue of the DRF command to the completion of the refresh operation has passed (step S18). A subsequent process can be performed for the banks for which the refresh operation is completed. In the example of FIG. 5, the time tRFC equivalent to 15 cycles is secured, and the ACT command for the bank 3 is issued at a subsequent cycle T19. The above described process of steps S11 to S18 is performed every time when the refresh interval is updated.

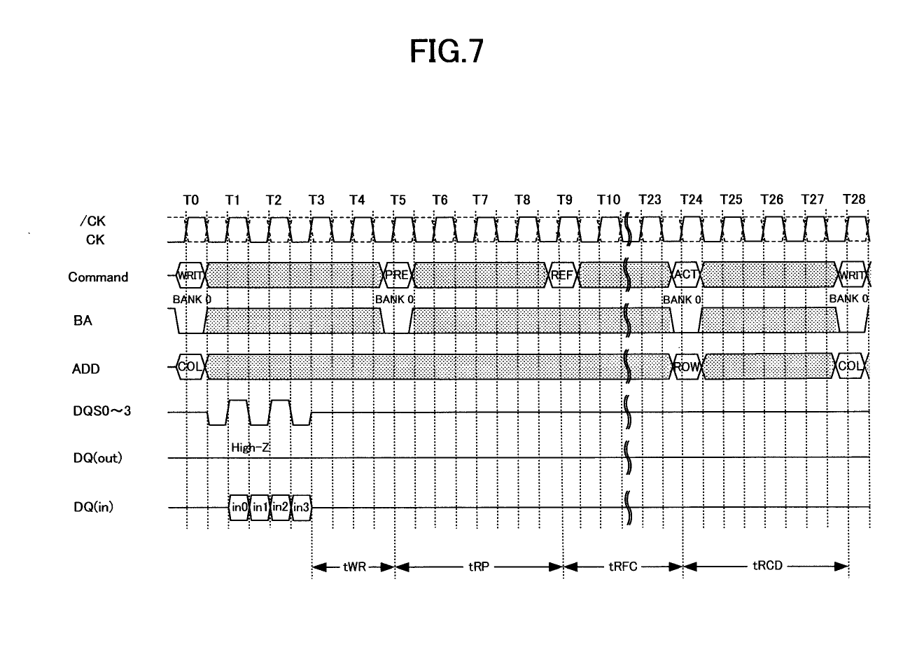

Here, FIG. 7 shows operation waveforms when a conventional auto-refresh operation is performed as a comparative example in order to explain the effect of the direct auto-refresh of the embodiment in comparison with the conventional auto-refresh. In the comparative example of FIG. 7, there are shown operation waveforms as to the clocks CK and /CK and a command, the bank address, the data strobes DQS0 to DQS3, the data output DQ(out), the data input DQ(in) like in FIG. 5. In this case, it is assumed that the DRF enable is previously set to 0 by the EMRS command so that the conventional auto-refresh operation is selectively set.

In FIG. 7, the WRIT command is issued to the bank 0 at a cycle T0. Thereby, the write operation is performed, and data inputs in0 to in3 are sequentially written to a corresponding address. A case in which the refresh interval is reached at the middle of the write operation will be considered. Since the auto-refresh operation is simultaneously performed for the four banks, the refresh operation can be performed at once when all of the banks 0 to 3 are in the idle state. However, in the example of FIG. 7, the bank 0 for which the burst write operation is performed is in the busy state, it is necessary to rapidly shift the bank 0 from the busy state to the idle state after once the write operation for the data to be written is completed. Note that this is the same for a case in which a read operation is performed instead of the write operation in FIG. 7.

Therefore, the PRE command for the bank 0 is issued at a cycle T5 at which a write recovery time tWR has passed from the output timing of a last data input in3, and the precharge operation for the bank 0 is performed. At this point, a time tRP is required from the issue timing of the PRE command until the bank 0 is actually placed in the idle state. Thus, in FIG. 7, the REF command is issued at a cycle T9 at which the time tRP has passed, and the refresh operation for the four banks 0 to 3 is performed.

When the time tRFC which is the same as in FIG. 5 has passed from the issue timing of the REF command, the refresh operation for the four banks 0 to 3 is completed. Subsequently, the ACT command for the bank 0 is issued at a cycle T24 at which the time tRFC has passed in order to resume the write operation for the bank 0. A time tRCD is required to start a subsequent operation from the issue timing of the ACT command. Thus, in FIG. 5, the WRIT command for the bank 0 is issued at a cycle T28 at which the time tRCD has passed, and thereby the burst write operation is continued.

In this manner, a time of tWR+tRP+tRFC+tRCD is required to perform the auto-refresh operation in a state where the bank in the busy state exists. In the comparative example of FIG. 7, tWR=2 cycles, tRP=4 cycles, tRFC=15 cycles, and tRCD=4 cycles are satisfied, and thus 25 cycles in total are required. Thereby, a time which can be used for other processes is consumed. In contrast, in the example of FIG. 5 in which the direct auto-refresh operation is performed, the auto-refresh operation for the banks in the idle state is performed for the time tRFC without interrupting the operation for the banks in the busy state. However, an effective process can be performed for the banks in the busy state within the time of 15 cycles which is required to complete the auto-refresh operation. In this case, since it is sufficient to perform operations of the lacking number of refresh operations for the banks in the busy state at appropriate timings (the detail of which will be described later), an efficiency of the operation can be improved.

In a control method employing the direct auto-refresh, the refresh operation is not performed for the banks in the busy state at the time the DRF command is issued, it is necessary to satisfy at least a demand for the refresh period. Even if the refresh operations at refresh intervals of, for example, 7.8 μs, are not performed several times, the refresh period does not exceed 64 ms by performing refresh operations for the banks for which the number of refresh operations is lacking at predetermined timings. Thus, a control method for replenishing the necessary number of times to refresh the banks for which the number of refresh operations is lacking at predetermined timings will be explained below.

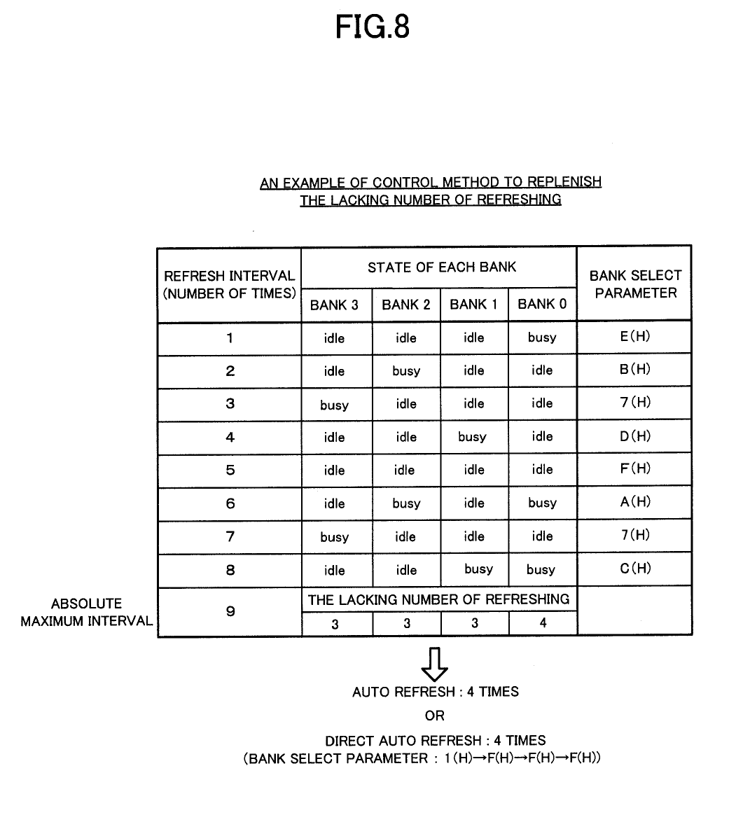

FIG. 8 shows a specific example of the control method for replenishing the lacking number of refresh operations for each bank. In the example of FIG. 8, a ninth refresh interval, which is subsequent to a series of eight times refresh intervals, is defined as an absolute maximum interval. With the absolute maximum interval, it is controlled so that the refresh operations are performed a number of times which is the maximum value of the lacking number of refresh operations for each bank after banks in the busy state are previously shifted to the idle state by a precharge operation, in which the number of refresh operations less than the eight times within the series of eight times refresh intervals in each bank and one time refreshing at the ninth refresh interval are added so that the added number of times are regarded as the lacking number of refresh operations.

For example, as shown in FIG. 8, since the bank 0 is in the busy state and the banks 1, 2 and 3 are in the idle state at the first refresh interval, the bank select data is set to E(H) and the DRF command is issued. Similarly, the DRF command is issued together with the bank select data corresponding to the states of the banks 0 to 3. Then, when the absolute maximum interval is reached, the lacking number of refresh operations for the bank 0 is four times because five times in the idle state and three times in the busy state are included in the eight times and onetime at the ninth are added thereto. On the other hand, the lacking number of refresh operations for each of the banks 1, 2 and 3 is three times because six times in the idle state and two times in the busy state are included in the eight times and one time at the ninth are added thereto. Thus, the maximum value of the lacking number of refresh operations is four for the bank 0, and it is sufficient to perform refresh operations four times continuously for each bank at the ninth as the absolute maximum interval.

Either the REF command or the DRF command may be used to replenish the lacking number of refresh operations. That is, when the REF command is used, it is sufficient to continuously perform auto-refresh operations four times by the REF command after setting 0 to the DRF enable DE of the extended mode register by the EMRS command. Further, when the DRF command is used, it is sufficient to continuously perform auto-refresh operations four times four times by the DRF command in a state where the bank select data is set to 1(H), F(H), F(H) and F(H) in this order. Note that an order for setting 1(H) as the bank select data need not to be fixed, and, for example, the order of F(H), F(H), F(H) and 1(H) may be employed. By performing such a control, the operation efficiency of the DRAM can be increased because it is not necessary to refresh banks in the busy state until the ninth refresh operation while satisfying the demand for the number of times to refresh at the absolute maximum interval.

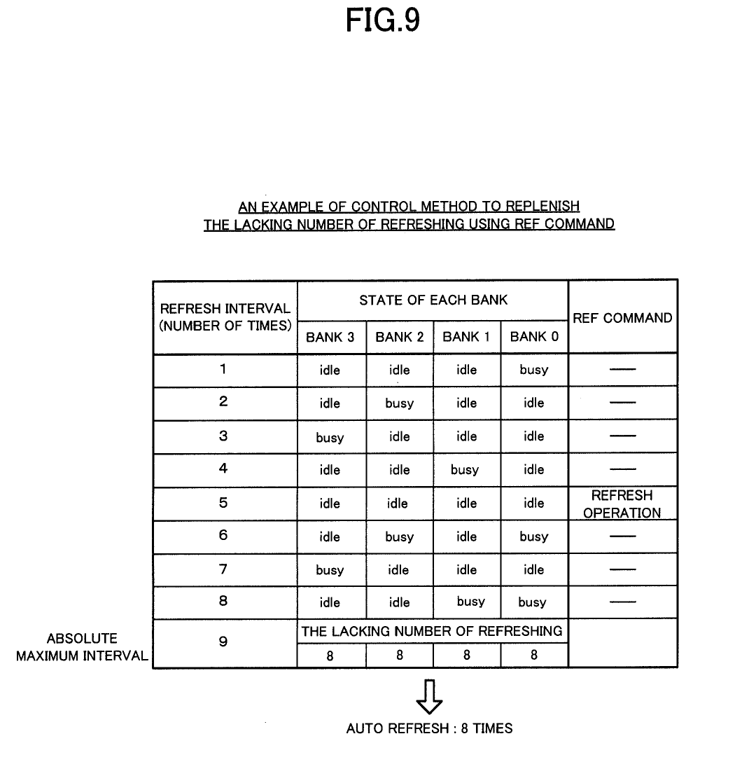

FIG. 9 shows a control method using only the conventional REF command as a comparative example for explaining the effect of the control method using the DRF command as shown in FIG. 8. The example of FIG. 9 shows a case in which the busy state and the idle state of the respective banks at the continuous eight refresh intervals are changed in the same manner as in FIG. 8. It is assumed in FIG. 9 that the control for shifting the banks in the busy state to the idle state (like in the example of FIG. 7) is not performed in the auto-refresh operation. In this case, even if only one bank is in the busy state, the REF command is not issued (it is assumed that the control for shifting from the busy state to the idle state as shown in FIG. 7 is not performed). Therefore, the refresh operation based on the REF command is performed only at the fifth refresh interval, at which all the banks are in the idle state, of the eight refresh intervals. Since the number of refresh operations is lacking at the other refresh intervals, the refresh operations must be continuously performed eight times in total at the ninth as the absolute maximum interval. Accordingly, the direct auto-refresh of the embodiment, which only requires four times refresh operations at the absolute maximum interval under the same condition, can obtain excellent operation efficiency.

Although the case in which the lacking number of refresh operations is replenished periodically at the absolute maximum interval has been explained in the control method shown in FIG. 8, the control method can be modified as described below. Specifically, the external controller counts the number of times not to perform the refresh operation for each bank, which is among refresh operations performed according to the busy/idle states of the respective banks using the DRF command at every refresh interval, and when the number of times not to perform the refresh operation reaches a predetermined number, the same control as that for the absolute maximum interval of FIG. 8 may be performed. For example, when the number of times not to perform the refresh operation reaches eight in a certain bank, the refresh operations are continuously performed nine times at the next refresh interval. When such a modification is employed, there is a possibility that the refresh operation is delayed by a maximum time equivalent to the eight times refresh intervals (62.5 μs). However this time is sufficiently short as compared with the refresh period of 64 ms and within a range of error (about 0.1%), so that it does not influence the data holding characteristics.

Although the present invention is specifically explained based on the embodiment, the present invention is not limited to the embodiment described above and can be variously modified within the scope which does not depart from the gist thereof. Although the case, in which the present invention is applied to, for example, the DRAM of the four bank arrangement, is explained, the present invention can be also applied to banks of an N-bank arrangement. In this case, bank select data must be set by 2N types of combination patterns including selection of N banks. In the embodiment, for example, the case is explained in which the DRF command and the REF command can be selectively used, it is also possible to use only the DRF command. In this case, the conventional REF command can be replaced by setting F(H) to the bank select data of FIG. 6. Further, in the embodiment, the case has been explained in which the DRF enable DE in the extended mode register is set when selecting the DRF command or the REF command. However, the DRF command and the REF command may be individually defined using a combination of different control signals in FIG. 2.

Although, in the embodiment, the case of applying the present invention to the DRAM as a semiconductor memory has been explained, the present invention can be also applied to a semiconductor memory other than the DRAM. Further, the present invention can be applied even to a case in which a memory system including a semiconductor memory is constructed.

This description is based on Japanese Patent Application No. 2005-216429 filed on Jul. 26, 2005, and all contents of the application are included herein.

### INDUSTRIAL APPLICABILITY

As described above, the present invention is applied to a semiconductor memory device having a plurality of banks each capable of being individually controlled, and is suitable to improve operating efficiency of the semiconductor memory device by performing a refresh operation in a short time.

1. A device comprising:
a plurality of banks each including a plurality of memory cells; and
a control circuit coupled to receive a refresh request that is issued a plurality of times during a predetermined period of time, the control circuit responding to each issuance of the refresh request to perform a refresh operation,
when the refresh request has been issued while each of the banks is in an inactive state, on each of the banks, and
when the refresh request has been issued while at least one of the banks is in an active state and remaining one or ones of the banks are in the inactive state, on at least one of the remaining one or ones of the banks with releasing the at least one of the banks from the refresh operation thereon.

2. The device as claimed in claim 1, wherein the control circuit is further coupled to receive a first address, the first address designating a bank or banks that are in the inactive state when the refresh request has been issued.

3. The device as claimed in claim 1, wherein the control circuit includes a plurality of refresh address generation circuits generating a plurality of refresh addresses independently to each other, the refresh addresses being supplied respectively to the banks.

4. The device as claimed in claim 1, wherein the control circuit further receives an additional refresh request that is issued when one or more banks of the banks exist in which a number of refresh operations which have been performed thereon during the predetermined period of time is less than the plurality of times of the refresh request issued during the predetermined period of time, the control circuit responding to the additional refresh request to perform an additional refresh operation on the one or more banks.

5. The device as claimed in claim 4, wherein the additional refresh request is issued one or more times before the predetermined period of time ends.
